(19) United States
(12) Patent Application Publication
(10) Pub. No.: US 2013/0037080 A1
(43) Pub. Date: Feb. 14, 2013

(54) TRANSPORTABLE SOLAR HARVESTER SYSTEM AND METHOD

(71) Applicants: Ron HELFAN, Hod Hasharon (IL); Gilad MOISA, Hod Hasharon (IL)

(72) Inventors: Ron HELFAN, Hod Hasharon (IL); Gilad MOISA, Hod Hasharon (IL)

(21) Appl. No.: 13/571,280

(22) Filed: Aug. 9, 2012

Related U.S. Application Data
(60) Provisional application No. 61/521,808, filed on Aug. 10, 2011.

(51) Int. Cl. H01L 31/045; H01L 31/052

(52) U.S. Cl. 136/245; 136/246

(57) ABSTRACT

A transportable solar harvester system for electrical generation in expeditionary, military, and commercial settings comprising: a photovoltaic array deployable in an open configuration and in a compact closed configuration; a set of stabilizing legs to enable stable positioning of the photovoltaic array in the open configuration; and an auxiliary power module connectable to the photovoltaic array, having system management functionalities to interface the system with other devices wherein the system is deployable from the compact closed configuration to the open configuration manually by two persons in less than 30 minutes and vice versa.

### METHOD

This application claims priority from U.S. Provisional Application no. 61/521,808, filed 10 Aug. 2011, whose disclosure is incorporated herein by reference.

### FIELD AND BACKGROUND OF THE INVENTION

Embodiments of the current invention are related to sustainable energy generation. More specifically, embodiments of the current invention relate to a transportable solar harvester system and method.

Sustainable energy sources are the subject of intense development over the past decades. The provision of energy to meet the needs of the present without compromising the ability of future generations to meet their energy needs is at the core of this idea. Sustainable energy sources most often regarded as including all renewable sources and technologies that improve upon existing fuel efficiencies. As such, solar energy has been a leading sustainable energy field of development.

One direction for development of solar energy is that of supplying electrical energy in remote, isolated, and/or military locations. For example, current military operations suffer from high and ever increasing battle-space fuel demands. Generators represent the largest single fuel consumers in a battlefield setting, second only to vehicles and transportation. Generator fuel consumption clearly has a negative overall impact on military capabilities and serves to increase support costs. Remote civilian location use of generators similarly represents a less optimal use of valuable and expensive fuel resources.

An example of prior art systems employing fuel-utilizing generators is that of the US Marine Corps' generators having various output sizes and configurations mounted on Light Tactical Trailers (LTT), as described by the US Marine Corps Systems Command, Henderson Hall, Arlington Va. and found in:

(http://www.marcorsyscom.usmc mil/sites/GTES/PM%20MT/TrailerLightTact icalMC.asp), as shown in the Appendix and which is incorporated herein by reference. A typical military trailer is described in the website of Olive Drab LLC, a Wyoming Limited Liability Company: (http://www. olive-drab.com/idphoto/id_photos_ltt-hmt_trailer_ltt-usmc.php_) and by the Program Manager or Expeditionary Power Systems of the Marine Corps Systems Command at:

(http://www.dtic mil/ndia/2007power/NDIAGrandExhibitHall/Wed/Ses sion13Tachtical.pdf), as shown in the Appendix and which are incorporated herein by reference.

Increased overall fuel efficiency, i.e. minimizing and/or eliminating conventional fuel electrical generation as well as reducing overall maintenance related to the generator work cycle, hold the promise of benefit to military and civilian applications not only in direct savings in fuel and maintenance costs, but—in the case of the military—also in contributing to increased combat effectiveness through the redirection of resources currently utilized for resupply.

Requirements for a renewable sustainable expeditionary power are described in a Broad Agency Announcement 11-002, by the US Office of Naval Research (ONR), 875 N. Randolph Street, Arlington, Va. 22203-1995 in: (http://www.onr.navy mil/˜/media/Files/Funding-Announcements/BAA/2011/11-002.ashx), as shown in the Appendix and which is incorporated herein by reference.

As noted hereinabove, a key element in addressing remote and military energy concerns is transportability. One example is a prior art system called a Mobile Solar Power Supply (MSPS), used for civilian and possible military uses is produced by Everphoton Energy Corp. 7F., No.201, Sec. 2, Tiding Blvd Taipei 11493, Taiwan, Everphoton, Taiwan (http://www.everphoton.com/emobilesupplypowersupply.htm), incorporated herein by reference. The prior art MSPS 2 comprises a solar array integrated with a vehicle.

High Concentration Photovoltaics (HCPV) technology is based on the concept of concentrating sunlight onto a high efficiency III-V Multi-Junction solar cell—which can operate efficiently at higher temperatures, when compared to conventional silicon solar cells. HCPV cells reach efficiencies of 40%, doubling the efficiency value of conventional Silicon-based cells used in flat plate PV systems. By using optics to concentrate sunlight, the cell size is reduced and system costs are reduced. One reference covering a wide array of recent developments and technology in this field is by Sarah Kurtz, “CPV 101: Intro to CPV Technology: Opportunities and Challenges”, NREL/PR-520-46924, 26 Oct. 2009, incorporated herein by reference.

Any transportable solar energy platform derived from the approaches discussed hereinabove must be robust—as the ability to withstand military and/or tough terrain transport and their associated environments is critical to operation and overall reliability. Additionally, renewable energy technology developments—such as, but not limited to HCPV and other technologies that show similar high efficiency potential would be advantageous for such transportable solar energy platforms.

There is therefore a need for a robust, cost effective, energy-efficient, and transportable photovoltaic system that is easily and flexibly deployed.

### SUMMARY OF THE INVENTION

According to the teachings of the present invention there is provided a transportable solar harvester system for electrical generation in expeditionary, military, and commercial settings comprising: a photovoltaic array deployable in an open configuration and in a compact closed configuration; a set of stabilizing legs to enable stable positioning of the photovoltaic array in the open configuration; and an auxiliary power module connectable to the photovoltaic array, having system management functionalities to interface the system with other devices, wherein the system is deployable from the compact closed configuration to the open configuration manually by two persons in less than 30 minutes and vice versa. Preferably, the photovoltaic array has at least one type of photovoltaic module chosen from the list including: flat plate PV, CPV and HCPV, and wherein the cell is a III-V multi junction cell. Most preferably, the system further comprises a dual-axis solar tracking system and a wind protection system. Typically, a transport cover is adapted to cover the system when the system is not deployed, the cover having one side with a thin film flexible PV integrated panel configurable to maximize solar collection of the system and to allow solar harvesting while the system is in the closed compact position and in transit.

Most typically, the solar photovoltaic array has a capacity of at least of 1 KWp. Preferably, the system is deployable in the field without the need for infrastructure work. Most preferably, the system is deployable and operatable on a non-level terrain having a slope of up to 20 degrees. Typically, the system is transportable in the compact closed configuration in a Light Tactical Trailer. Most typically, dimensions of the system in the compact closed configuration are not in excess of substantially 87.5 inches width and 135 inches length. Preferably, a crate is adapted to transport the system therein in the compact closed configuration and wherein crate dimensions are not in excess of substantially 220 cm×300 cm×160 cm. Most preferably, other devices are at least one chosen from the list including: a transport vehicle; an external battery; an electrical grid; a diesel generator; a turbine; an external load.

Typically, the system has a power configuration and controls adapted to allow the system to serve as a micro grid. Most typically, the system is adapted to charge batteries and support DC and AC loads. Preferably, the system further includes: at least one MPPT unit; a PV charger; an inverter/charger; a battery bank; and fuel cells. Most preferably, the system includes a diesel generator. Most preferably, the system is operatable within MILSTD 810 g and f requirements. Typically, the system is operatable fully automatically following deployment.

According to the teachings of the present invention there is further provided a method of using a transportable solar harvester system for electrical generation in expeditionary, military, and commercial settings comprising the steps of: deploying a photovoltaic array from a closed configuration to an open configuration; utilizing a set of stabilizing legs to enable stable positioning of the photovoltaic array in the open configuration; and connecting an auxiliary power module connectable to the photovoltaic array, having system management functionalities and interfacing the system with other devices whereby the system is deployed from the compact closed configuration to the open configuration manually by two persons in less than 30 minutes and vice versa. Preferably, the photovoltaic array has at least one type of photovoltaic module chosen from the list including: flat plate PV, CPV and HCPV, and wherein the cell is a III-V multi junction cell.

### BRIEF DESCRIPTION OF THE DRAWINGS AND APPENDICES

The invention is herein described, by way of example only, with reference to the accompanying drawings, wherein:

FIGS. 1-4 are pictorial representations of a mobile solar harvester system, in accordance with embodiments of the current invention.

### DETAILED DESCRIPTION OF THE PREFERRED EMBODIMENTS

Embodiments of the current invention are related to sustainable energy generation. More specifically, embodiments of the current invention relate to a transportable solar harvester system and method.

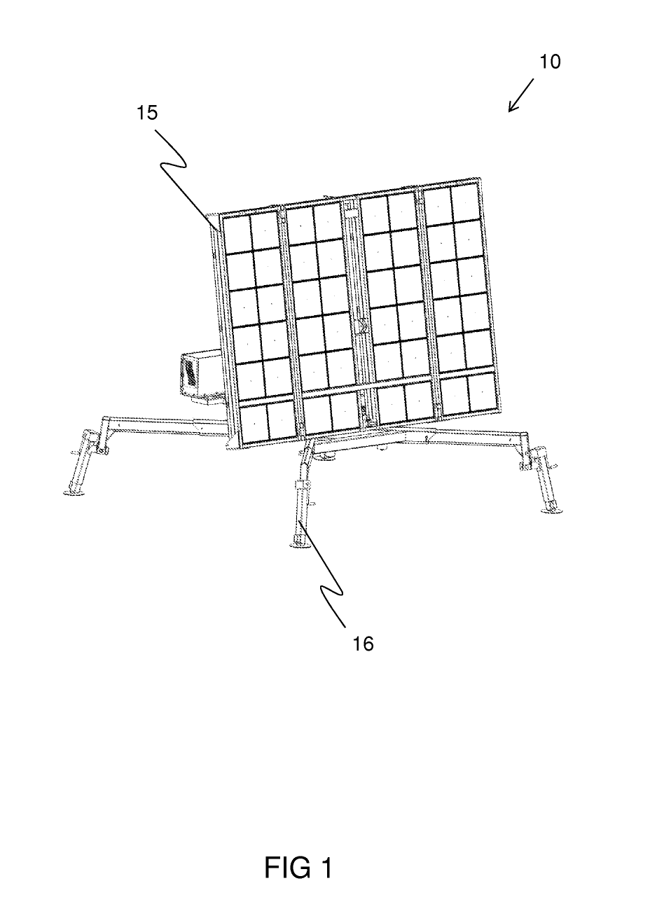

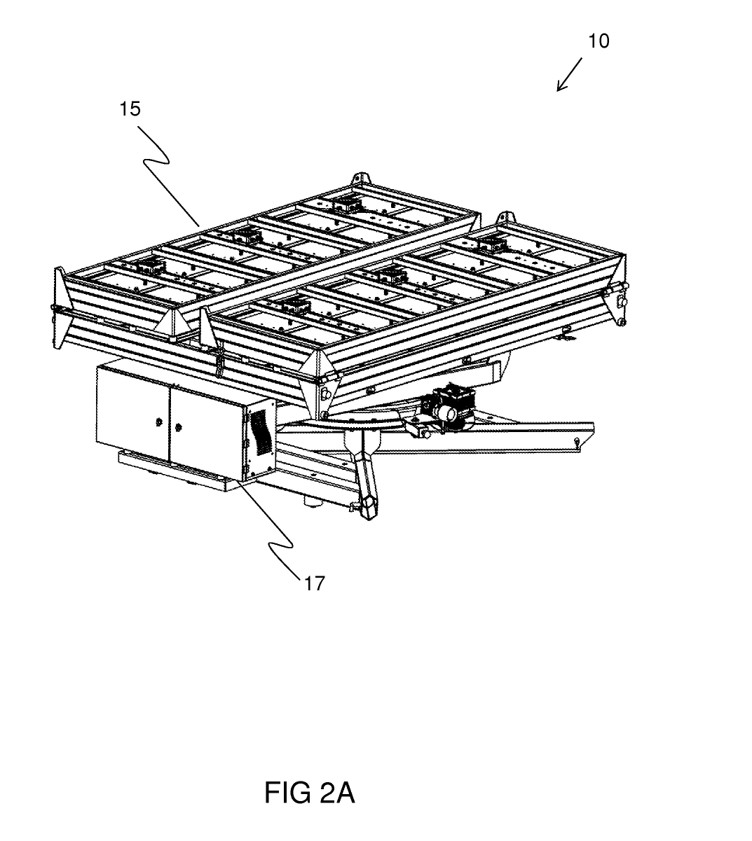

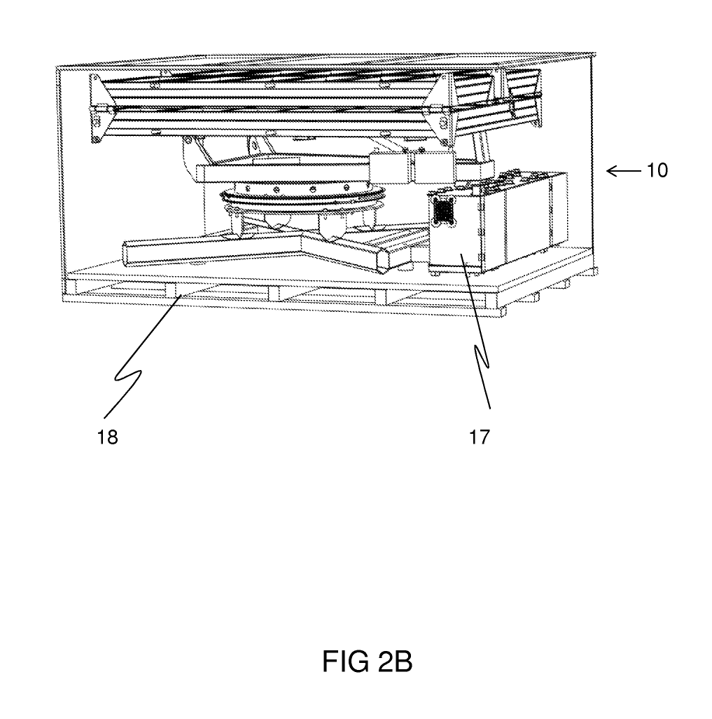

Reference is currently made to FIGS. 1-4, which are pictorial representations of a transportable solar harvester system 10, in accordance with embodiments of the current invention. System 10 incorporates a high concentration photovoltaic array 15 (herein referred to alternatively as “HCPV array” and having one or more high concentration photovoltaic modules therein) having stabilizing deployable and adjustable legs 16 and a battery/auxiliary power module 17 including a command & power control board (not shown in the figure). The photovoltaic array may be deployed in a deployed free standing configuration (ref FIG. 1)—otherwise referred to as an “open configuration”—or stowed as described hereinbelow. The system may be transported in a crate 18. The crate shown in the figure is in a partially opened configuration. FIG. 2A shows the system in a stowed configuration)—otherwise referred to hereinbelow as a “compact closed configuration”—and FIG. 2B shows an exemplary stowed-in-crate configuration suitable for system air and naval transportability by commercial and/or cargo and/or military craft.

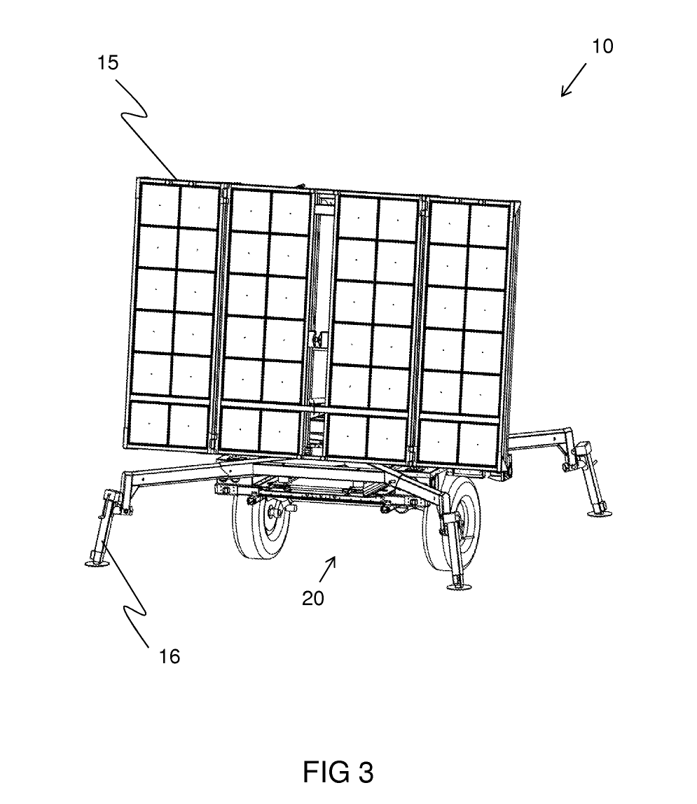

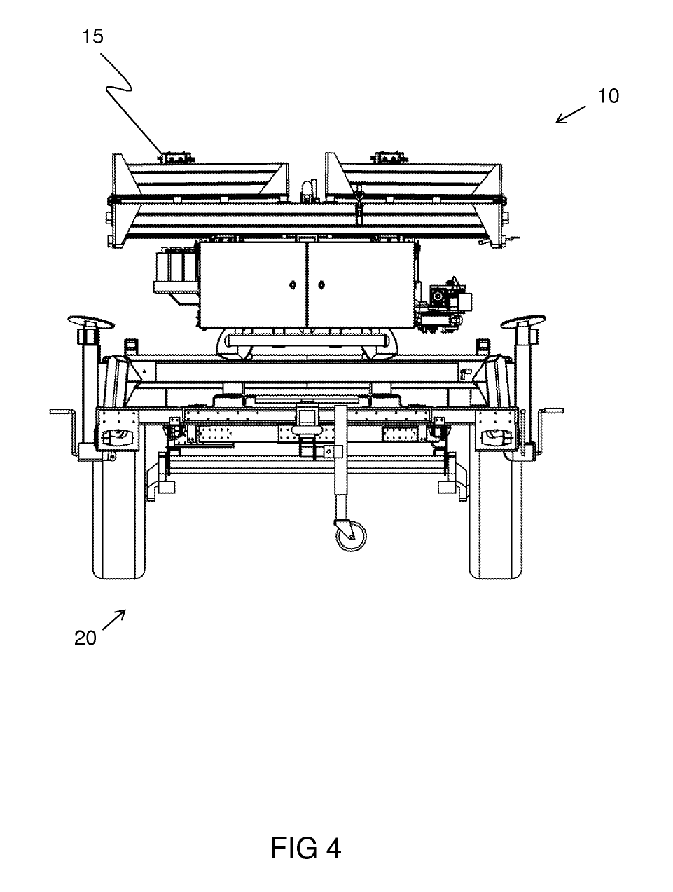

Alternatively or optionally, the system may be attached and detached to a trailer 20 for flexible ground transport, as shown in FIGS. 3 and 4, in deployed and stowed configurations, respectively.

HCPV array 15 can employ a Fresnel-based primary optics system (not shown in the figures) to concentrate light onto a III-V multi-junction cell. Secondary glass optics may be used in the optics system to increase light incidence onto the cell. A dual-axis tracking system (not shown in the figures) is used to maintain substantial alignment of photovoltaic array 15 with the sun during the day. The dual-axis tracking system employs a solar trajectory algorithm and\or solar position sensor.

In embodiments of the current invention, the system is manually deployed by two persons in less than 30 minutes. The system may be deployed in non-leveled terrains having slopes of up to 20 degrees without significant or any decrease in system performance. Once deployed, the system operates fully automatically, ie in a, hands-free, manner.

At wind speeds of approximately 60-70 km/hr, the system automatically stows into a wind-protection configuration, which may be the compact closed configuration. The system is designed to withstand wind speeds of up to approximately 140 km\hr in the stowed wind-protection configuration. Wind speed and direction are measured using a wind sensor/anemometer (as known in the art) which is connected to a tracker control board (not shown in the figures) of power module 16.

Transportable solar harvester system 10 may be used off-grid (i.e. not connected to an electrical grid) for backup in civilian and military applications. Alternatively or optionally, the system may be incorporated into a “solar farm”, as known in the art, to feed excess-generated electricity into the electrical grid.

Embodiments of the current invention include:

a design which allows the system to provide output at remote locations without dependency on an electrical grid;

a photovoltaic array of 1 KWp to 5 KWp, optionally employing CPV and HCPV technology;

field-deployable without a need for any infrastructure work such as, but not limited to concrete foundations;

deliverable in a compact stowed position, i.e. “compact closed configuration”, minimizing transportability dimensions to enable:
transportable in standard aircraft and in standard shipment freight containers used for sea transportation; e.g. crate dimensions of approximately 220×300×160 cm;
integration into standard military trailers so that in stowed position, the dimensions of the system do not exceed the trailer's dimensions. For example, in case of an USMC LTT chassis, the system in its stowed position does not exceed 87.5 inches width and 135 inches length;

can be integrated into a light trailer having a vehicle curb weight of up to 5,000 lbs—such as light tactical trailers used by the USMC and US Military. For this purpose steel, aluminum and composite materials are used in the chassis and structure of the system;

optionally or additionally, may be installed onto vehicles such as pick-up trucks or tactical vehicles such as, but not limited to: HMMWV and APC;

retractable legs are used to level the system as well as provide stability, especially in windy conditions;

retractable legs are lockable in several positions for transportation, stowing, and delivery;

may be deployed manually and/or with the assistance of electro-mechanical devices;

each sub-assembly, photovoltaic array, and components that may be required to be handled and/or maintained in the field do not exceed 88 lbs. weight;

chassis and structure may be made of lightweight and composite materials to meet critical weight requirements;

equipped with shock absorbers to allow transport in harsh terrains, optionally or additionally with in line with shock and vibration MILSTD 810 requirements, herein referred to as “MILSTD 810 g and f”, which is incorporated herein by reference.

the system may be further modified to allow parachute-drop deployment from an aircraft such as but not limited to a C130

designed to operate in harsh climates such as from approximately −40 C to approximately +60 C, relative humidity of up to 100%, and wind speeds as noted hereinabove;

optionally or alternatively, equipped with an active dehumidifying system designed to operate automatically, periodically, or manually to prevent condensation and maintain reliability;

power configuration is designed to have system serve as a “micro grid” and to electrically sustain itself by charging batteries and/or supporting DC and AC loads;

power architecture consisting of a PV MPPT charger, a battery pack, and an inverter\charger unit;

inverter\charger unit capable of converting DC output to AC to support AC loads and to charge batteries from an AC source such as a conventional generator or the electrical grid;

optionally or additionally, may integrate a conventional AC generator connected to the inverter\charger unit, such as a MEP-802A or MEP-831A Fermont tactical generator;

optionally or additionally, may integrate with a DC diesel generator;

start and shut down of diesel generators are integratable, with the system having controls and hardware, as known in the art, to allow functioning according to generation, load, and storage considerations;

optionally or additionally, may include wind turbines for electrical generation;

optionally or additionally, may include additional PV platforms such as GREENS for additional capacity , refer to: (http://www.dtic.mil/ndia/2011power/Session8_{—}12081Govar.pdf)

may support loads “on the go” meaning, for example, that output may be drawn from the battery pack to the towing vehicle when the system is being towed/transported.

A transport cover (not shown in the figures) is used to cover the system when it is not deployed. The cover may be fabricated from a double sided material, as known in the art, with one side having a thin film flexible PV integrated panel. The main purposes of the transport cover are to:

Maximize the solar collection of the system; and

Allow solar harvesting while in stowed position and in transit.

In embodiments of the current invention an exemplary use of the system to generate electricity involves the following steps:
1. Deploying a photovoltaic array from a closed configuration to an open configuration;
2. utilizing a set of stabilizing legs to enable stable positioning of the photovoltaic array in the open configuration; and
3. connecting an auxiliary power module connectable to the photovoltaic array, having system management functionalities and interfacing the system with other devices,

In the steps above, the system may be deployed, from the compact closed configuration to the at least one open configuration and vice versa, manually by two persons in less than 30 minutes.

Although applications and configurations illustrated hereinabove for military settings, embodiments of the current invention embrace commercial and/or civilian applications, mutatis mutandis.

It will be appreciated that the above descriptions are intended only to serve as examples, and that many other embodiments are possible within the scope of the present invention as defined in the appended claims.

1. A transportable solar harvester system for electrical generation in expeditionary, military, and commercial settings comprising:
a photovoltaic array deployable in an open configuration and in a compact closed configuration;
a set of stabilizing legs to enable stable positioning of the photovoltaic array in the open configuration; and
an auxiliary power module connectable to the photovoltaic array, having system management functionalities to interface the system with other devices,
wherein the system is deployable from the compact closed configuration to the open configuration manually by two persons in less than 30 minutes and vice versa.

2. The system of claim 1, wherein the photovoltaic array has at least one type of photovoltaic module chosen from the list including: flat plate PV, CPV and HCPV, and wherein the cell is a III-V multi junction cell.

3. The system of claim 2, wherein the system further comprises a dual-axis solar tracking system and a wind protection system.

4. The system of claim 3, wherein a transport cover is adapted to cover the system when the system is not deployed, the cover having one side with a thin film flexible PV integrated panel configurable to maximize solar collection of the system and to allow solar harvesting while the system is in the closed compact position and in transit.

5. The system of claim 4, wherein the solar photovoltaic array has a capacity of at least of 1 KWp.

6. The system of claim 5, wherein the system is deployable in the field without the need for infrastructure work.

7. The system of claim 6, wherein the system is deployable and operatable on a non-level terrain having a slope of up to 20 degrees.

8. The system of claim 2, wherein the system is transportable in the compact closed configuration in a Light Tactical Trailer.

9. The system of claim 8, wherein dimensions of the system in the compact closed configuration are not in excess of substantially 87.5 inches width and 135 inches length.

10. The system of claim 8, wherein a crate is adapted to transport the system therein in the compact closed configuration and wherein crate dimensions are not in excess of substantially 220 cm×300 cm×160 cm.

11. The system of claim 1, wherein other devices are at least one chosen from the list including: a transport vehicle; an external battery; an electrical grid; a diesel generator; a turbine; an external load.

12. The system of claim 2, wherein the system has a power configuration and controls adapted to allow the system to serve as a micro grid.

13. The system of claim 1, wherein the system is adapted to charge batteries and support DC and AC loads.

14. The system of claim 13, wherein the system further includes: at least one MPPT unit; a PV charger; an inverter/charger; a battery bank; and fuel cells.

15. The system of claim 13, wherein the system includes a diesel generator.

16. The system of claim 2, wherein the system is operatable within MILSTD 810 g and f requirements.

17. The system of claim 2, wherein the system is operatable fully automatically following deployment.

18. A method of using a transportable solar harvester system for electrical generation in expeditionary, military, and commercial settings comprising the steps of:
deploying a photovoltaic array from a closed configuration to an open configuration;
utilizing a set of stabilizing legs to enable stable positioning of the photovoltaic array in the open configuration; and
connecting an auxiliary power module connectable to the photovoltaic array, having system management functionalities and interfacing the system with other devices
whereby the system is deployed from the compact closed configuration to the open configuration manually by two persons in less than 30 minutes and vice versa.

19. The method of claim 18, whereby the photovoltaic array has at least one type of photovoltaic module chosen from the list including: flat plate PV, CPV and HCPV, and wherein the cell is a III-V multi junction cell.
